(19) United States
(12) Patent Application Publication
(10) Pub. No.: US 2006/0131692 A1
(43) Pub. Date: Jun. 22, 2006

(54) Light-emitting device

(76) Inventors: Hidetoshi Saitoh, Niigata (JP); Shigeo Ohshio, Niigata (JP); Yusuke Fukada, Niigata (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(21) Appl. No.: 10/528,369

(22) PCT Filed: Sep. 19, 2003
(86) PCT No.: PCT/JP03/11968

§ 371 Date: Oct. 7, 2005

(30) Foreign Application Priority Data
Sep. 20, 2002 (JP) 2002-274321

(51) Int. Cl. H01L 27/082

(52) U.S. Cl. 257/565

(57) ABSTRACT

An object of the present invention is to provide at a low cost a light emitting device capable of emitting light not only in a visible light region, but also in an ultraviolet ray region and an infrared ray region with a high luminance and, further, capable of being reduced in size. According to the present invention, in the light emitting device (1) in which a light emitting electrode (4) and a cold cathode (3) are disposed opposite to each other, the light emitting electrode (4) is constituted by a metal oxide structure having whiskers (15) of a metal oxide. As for the metal oxide which constitutes the whiskers, it is preferable to use such metal oxide as has a band gap of from 1.5 to 7.7 eV. The light emitting electrode and the cold cathode are disposed within a vacuum chamber or a container having a base body sealed therein.

### TECHNICAL FIELD

The present invention relates to a light emitting device to be used in light sources of various types of displays and OA apparatuses, lighting fixtures and the like.

### BACKGROUND ART

As for a light emitting apparatus comprising an electron emitting device and a phosphor, known is a cathode ray tube, in which a hot cathode device is used as the electron emitting device. However, since an electron is emitted by a thermal energy, there is a drawback in that energy efficiency is low.

In order to eliminate such drawback as described above, a light emitting apparatus comprising a cold cathode device which does not use the thermal energy as the electron emitting device has been developed. For example, a device using a so-called spindt-type cold cathode provided with a multiplicity of emitter tips each in a minute triangular pyramid shape is known as the cold cathode device.

However, the device has problems in that it is difficult to produce a multiplicity of emitter chips in a highly precise manner, an amount of electrons to be emitted varies, a service life of the device is short and the like.

In order to improve these problems, it is proposed to constitute the cold cathode which is the electron emitting device by whiskers comprising a metal oxide or the like (for example, JP-A Nos. 2001-35424 and 2001-357771 being referred).

### DISCLOSURE OF THE INVENTION

Although problems on the production of the spindt-type cathode device are solved to certain extent by techniques described in the above-cited patent documents, a sufficient luminance required for a light emitting apparatus can sometimes not be obtained depending on applications and, further, a wavelength of light to be emitted from the apparatus is limited up to that of a blue color and, accordingly, light in an ultraviolet ray region can not be obtained. Furthermore, there is a drawback in that it is difficult to reduce the size of the apparatus.

Therefore, an object of the present invention is to solve these problems of conventional techniques and to provide at a low cost a light emitting device capable of emitting light not only in a visible light region but also in an ultraviolet ray region and an infrared ray region having a high luminance and, further, capable of being reduced in size.

The present inventors have exerted an intensive study and, as a result, have found that, in a light emitting device in which a light emitting electrode (phosphor) and a cold cathode are disposed opposite to each other, the above-described problems can be solved by constituting the light emitting electrode by whiskers of a metal oxide, to thereby achieve the present invention.

Namely, according to the present invention, following constitutions are adopted.

1. A light emitting device, wherein a light emitting electrode and a cold cathode are disposed opposite to each other, wherein the light emitting electrode is constituted by a metal oxide structure having whiskers of a metal oxide.

2. The light emitting device according to 1, wherein a band gap of the metal oxide constituting the whiskers is from 1.5 to 7.7 eV.

3. The light emitting device according to 1 or 2, wherein a diameter of a cross-section of an approximate circle of the whisker is from 0.01 to 100 μm and a ratio of length of the whisker to the diameter of the cross-section of the approximate circle of the whisker is from 1 to 10000.

4. The light emitting device according to any one of 1 to 3, wherein the whiskers are present in a density of from 0.1 to 10000 pieces per area of 10 μm×10 μm on a surface of the metal oxide.

5. The light emitting device according to any one of 1 to 4, wherein the whiskers comprise an element different from that of a main material which constitutes the whiskers.

6. The light emitting device according to any one of 1 to 5, wherein the whiskers can be obtained by allowing the metal oxide to be epitaxially grown on a surface of a substrate.

7. The light emitting device according to any one of 1 to 6, wherein zinc oxide is used as the main material which constitutes the whiskers.

8. The light emitting device according to any one of 1 to 7, wherein a light emitting electrode is constituted by the metal oxide structure in which spaces between whiskers are filled with a material selected from among an organic substance, an inorganic substance and a metal.

9. The light emitting device according to any one of 1 to 8, wherein the cold cathode is constituted by the metal oxide structure having the whiskers of the metal oxide.

10. The light emitting device according to any one of 1 to 9, wherein the cold cathode is constituted by a carbonaceous material selected from the group consisting of a carbon nanotube, fullerene, diamond, graphite and a carbon fiber.

11. The light emitting device according to any one of 1 to 10, wherein the light emitting electrode and the cold cathode are disposed in a vacuum chamber or a container having a gas sealed therein.

12. The light emitting device according to any one of 1 to 10, wherein the light emitting electrode in a planar shape and the cold cathode in a planar shape are disposed opposite to each other in the container.

13. The light emitting device according to 12, wherein a reflecting plate is provided on one side face of a space defined by the light emitting electrode and the cold cathode.

14. The light emitting device according toll, wherein the light emitting electrode is disposed on an inner surface of the container and the cold cathode is disposed in a center portion of the container.

### BRIEF DESCRIPTION OF THE DRAWINGS

FIG. 1 is a schematic diagram showing an example of an atmospheric open type CVD apparatus for producing a material which constitutes a light emitting electrode or a cold cathode of a light emitting device according to the present invention.

FIG. 2 is a schematic diagram showing another example of an atmospheric open type CVD apparatus for producing a material which constitutes a light emitting electrode or a cold cathode of a light emitting device according to the present invention.

FIG. 3 is a schematic diagram showing an example of a light emitting device according to the present invention.

FIG. 4 is a schematic diagram showing another example of a light emitting device according to the present invention.

FIG. 5 shows schematic diagrams of still another example of a light emitting device according to the present invention, wherein (A) shows a perspective diagram thereof and (B) shows a cross-sectional diagram thereof.

FIG. 6 is a schematic diagram showing further still another example of a light emitting device according to the present invention.

### BEST MODE FOR CARRYING OUT THE INVENTION

The present invention is characterized in that a light emitting electrode of a light emitting device in which the light emitting electrode and a cold cathode are disposed opposite to each other, is constituted by a metal oxide structure having whiskers of a metal oxide.

The whisker according to the present invention means an article having a structure in an approximate rod shape in which a diameter of a cross-section of an approximate circle is from 0.01 to 100 μm (average value; hereinafter, the same holding true) and length to the diameter of the cross-section of the approximate circle (aspect ratio) is 1 or more. Further, the length of the whisker means a length of from a position (base portion) on which the whisker is substantially protruded from a surface to a tip portion and the diameter of the cross-section of the approximate circle is measured at a position of half the length of the whisker. As far as the diameter of the cross-section of the approximate circle is concerned, firstly, a cross-section area is obtained by using a known method, for example, an image analysis and, subsequently, the thus-obtained area is divided by a circle ratio a, subjected to a square root and multiplied by 2 to obtain a value and, then, the diameter of the cross-section of the approximate circle is expressed by the thus-obtained value.

When the diameter of the cross-section of the approximate circle of the whisker is less than 0.01 μm, it is difficult to obtain grown whiskers, while, when it is more than 100 μm, it becomes difficult to obtain desired characteristics due to an increase of a surface area obtained by the whiskers. The diameter of the cross-section of the approximate circle is preferably from 0.05 to 50 μm and, particularly preferably, from 0.1 to 10 μm.

Although the length of the whisker is selected depending on applications to be used, it is ordinarily from 0.1 to 1000 μm (average value) and, preferably, from 1 to 500 μm. Further, the aspect ratio is 1 or more and, preferably, 5 or more. When the aspect ratio is unduly small, an effect of the increase of the surface area obtained by the whiskers is not exhibited.

It is preferable that the whiskers are present in a dense state at a ratio in the range of from 0.1 to 10000 pieces per area of 10 μm×10 μm and, particularly, in the range of from 1 to 1000 pieces per area of 10 μm×10 μm. When the ratio is smaller than these ranges, the effect of the increase of the surface area obtained by the whiskers is scarcely obtained, while, when it is larger than these ranges, it becomes difficult to obtain the grown whiskers.

Examples of shapes of such whiskers include a shape in which a diameter does not change from a base portion through a tip portion, another shape in which a diameter does not change in a certain distance from a base portion, still another shape in which a diameter is small at a base portion, once increased and, then, gradually decreased toward a tip portion, a shape with a tip portion selected from pyramid, truncated pyramid, cone, truncated cone or semisphere and the like; or combinations of these shapes. As for preferable shapes, a columnar or prismatic shape, a shape in which the diameter of the base portion of the whiskers is small and it once becomes large and, then, becomes prismatic toward the tip portion, and the like can be used. When it is a prism shape, although a substantial shape varies depending on crystalline structures, for example, in a case in which the metal oxide is zinc oxide, it often becomes a hexagonal prism, in a case in which the metal oxide is yttrium, it often becomes a tetragonal prism or a hexagonal prism and, in a case in which the metal oxide is titanium oxide, it often becomes tetragonal prism. Further, it goes without saying that the shape may be a prism having a cross-section of any of other polygon shapes. Two sides facing each other in a same prism may not be parallel to each other.

According to the present invention, as for metal oxides constituting whiskers, oxides of elements in which metal species belong in the periodic table to the group 1 excluding hydrogen and the group 2, the group 13 excluding boron, the group 14 excluding carbon, the group 15 excluding nitrogen, phosphorous and arsenic, groups 3, 4, 5, 6, 7, 8, 9, 10, 11 and 12 can be used. As for metal species, for example, Li, Na, K, Rb, Cs, Be, Mg, Ca, Sr, Ba, Al, Ga, In, Tl, Si, Ge, Sn, Pb, Sb, Bi, Po, Sc, Y, La, Th, Ce, Pr, Nd, Pm, Sm, Eu, Gd, Tb, Dy, Ho, Er, Tm, Yb, Lu, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd and Hg can be used. Among these metal species, Li, Na, K, Rb, Cs, Be, Mg, Ca, Sr, Ba, Al, Ga, In, Tl, Si, Ge, Sn, Pb, Sb, Bi, Sc, Y, La, Ce, Th, Ti, Zr, Hf, V, Nb, Ta, Cr, Mo, W, Mn, Re, Fe, Ru, Os, Co, Rh, Ir, Ni, Pd, Pt, Cu, Ag, Au, Zn, Cd, Hg, Eu, Tb, Tm and Yb are preferably used, and Li, K, Hf, Ca, Sr, Ba, Al, In, Si, Sn, Pb, Th, Y, Ce, Ti, Zr, V, Nb, Ta, Cr, Mo, W, Mn, Fe, Co, Ni, Pd, Pt, Cu, Ag, Zn, Ga, W, Eu, Tb, Tm and Yb are more preferably used.

As for preferable metal species, Y, Eu, Tb, Tm, Ba, Ca, In, Al, Mn, Zn, Ti, Sn, Sr, Hf, Zr, Cr, Ce, Pb and W are illustrated. These metal species can be used either solely or in combinations of two types or more. Further, it is also permissible to allow light emitting characteristics to be improved by containing the element different from the main material which constitutes the whiskers, as an activator, in the whiskers.

As for preferable metal oxides, for example, ZrO₂, Al₂O₃, In₂O₃, SiO₂, SnO₂, TiO₂, ZnO, barium titanate, SrTiO₃, LiNiO₃, PZT, YBCO, YSZ, YAG and ITO (In₂O₃/SnO₂) are listed. Further, an article in which Al₂O₃ is doped in ZnO may be permissible. Still further, composite oxides such as KTaO₃ and NbLiO₃ may also be permissible.

When the metal oxide structure having the whiskers is prepared by using the metal oxide having a band gap of from 1.5 to 7.7 eV among the metal oxides by means of the atmospheric open type CVD method, a free exciton luminescence having an energy approximately equivalent to the band gap can be obtained; such case as described above is particularly preferable.

Since the free exciton luminescence allows an ultraviolet ray or a strong luminescence of blue color to be emitted, it is useful as a light source of, for example, an OA apparatus or an optical communication.

The whiskers obtained from the metal oxide having a band gap of from 1.78 to 3.11 eV exhibit a strong luminescence in a visible light region of from 400 to 700 nm. As for such metal oxides as described above, indium oxide (2.7 eV), Cu₂O (2.0 eV) and the like are listed.

Further, the whiskers obtained from the metal oxide having a band gap of from 3.11 to 6.23 eV exhibits a strong luminescence in an ultraviolet ray region of from 200 to 400 nm; as for such metal oxides as described above, ZnO (3.2 eV), CoO (4.0 eV), Cr₂O₃ (3.3 eV), MnO (3.6 eV), NiO (4.2 eV), SnO₂ (3.6 eV), Ta₂O₅ (4.2 eV), Y₂O₃ (5.5 eV), ZrO₂ (5.0 eV), HfO₂ (6.0 eV) and the like are listed.

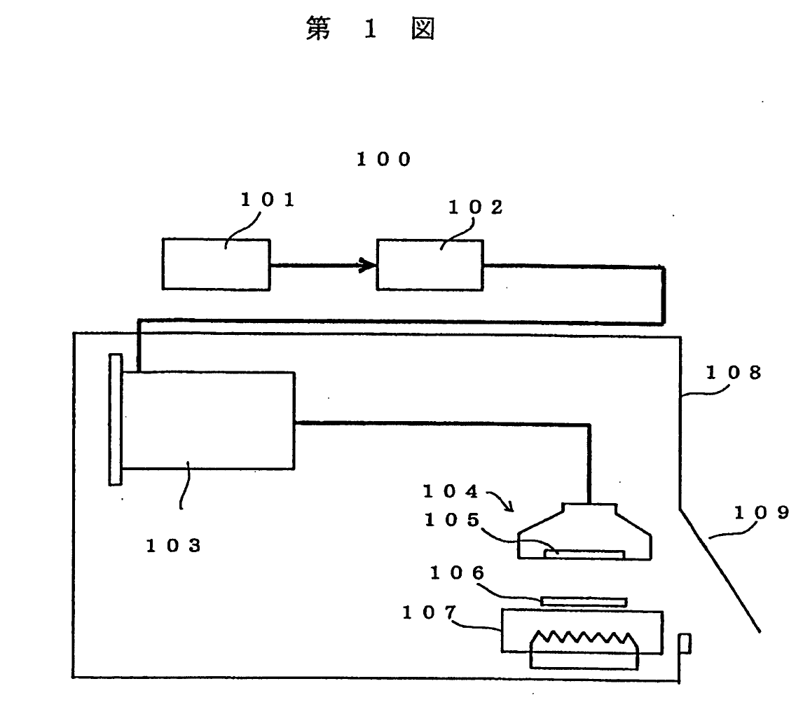

The metal oxide structure having the whiskers of the metal oxide constituting the light emitting electrode of the light emitting device according to the present invention can be produced by using, for example, the atmospheric open type CVD method as shown in FIG. 1.

FIG. 1 is a schematic diagram of an apparatus for producing a metal oxide structure to be used in the present invention.

In FIG. 1, a reference numeral 100 represents a production apparatus; a reference numeral 101 represents a dry nitrogen supply source such as a cylinder for supplying dry nitrogen which becomes a carrier gas; a reference numeral 102 represents a flow meter; a reference numeral 103 represents a raw material vaporizer for forming a metal oxide film; a reference numeral 104 represents a nozzle provided with a slit 105 having a specified width; a reference numeral 106 represents a substrate; and a reference numeral 107 represents a heating stage for the substrate 106. Further, the vaporizer 103, the nozzle 104, the substrate 106 and the heating stage 107 are covered by a protective chamber 108. The protective chamber 108 is provided with a door 109 made of an acrylic resin or the like.

A raw material which is evaporated by heating in the raw material vaporizer 103 is sent to the nozzle 104 together with a nitrogen gas, blown off into the air from the slit 105 having the specified width provided on the nozzle 104 and, then, blown on a surface of the heated substrate 106. The thus-blown raw material is decomposed in the air and, then, the metal oxide structure having the metal oxide whiskers is formed on the surface of the substrate.

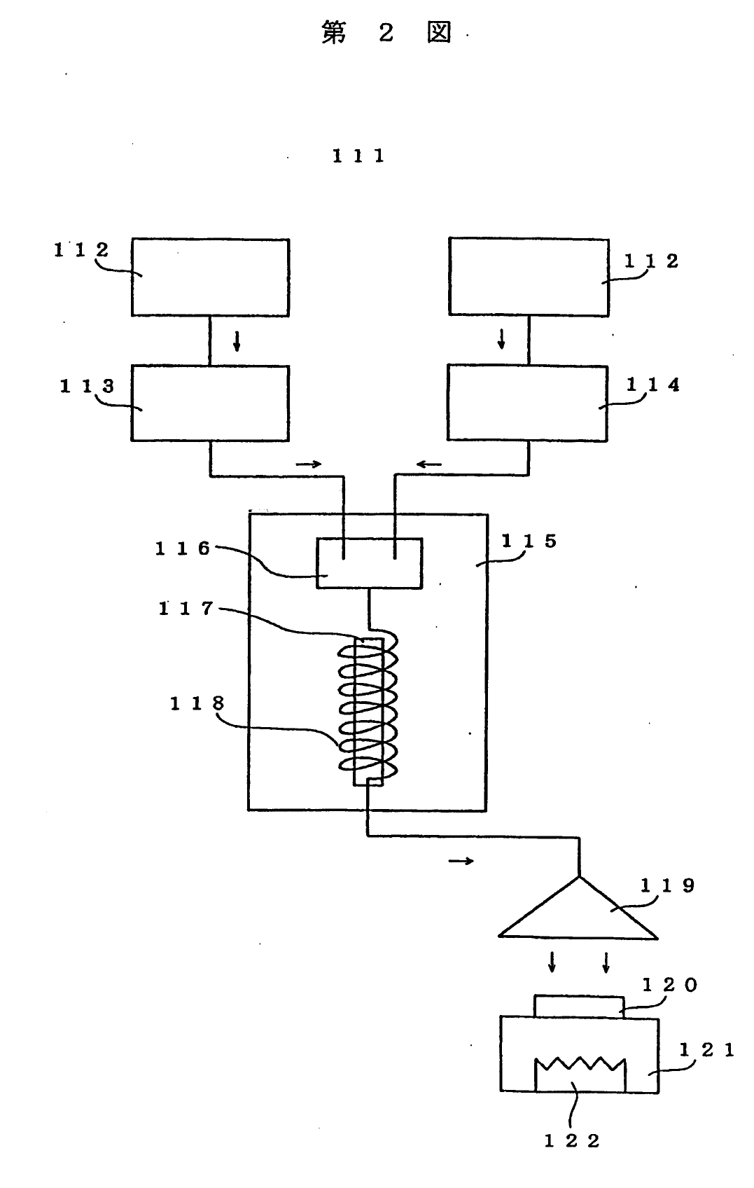

A metal oxide structure containing an element different from a main material constituting whiskers in the whiskers can be produced by using, for example, a production apparatus as shown in FIG. 2.

This production apparatus 111 comprises nitrogen gas supply sources 112, 112 for supplying a nitrogen gas which becomes a carrier gas, a vaporizer 113 for a main material which constitutes metal oxide whiskers, another vaporizer 114 for an element different from the main material, a raw material mixer 115 for uniformly mixing the thus-vaporized main material and the element different from the main material together with the carrier gas, a nozzle 119 for blowing off the thus-mixed raw material gas and a heating stage 121 for a substrate 120.

The main material constituting the metal oxide whiskers and the element different from the main material are vaporized by heating in respective vaporizers 113 and 114, sent to a raw material mixing reservoir 116 inside the raw material mixer 115 and, then, uniformly mixed with the carrier gas by a heat-mixer 118 in a coil state provided in an outer circumference of a heater 117. The thus-uniformly mixed raw material gas is blown on a surface of the substrate 120 heated on the heating stage 121 having the heater 122 from the nozzle 119 under an opened atmospheric pressure, to thereby form the metal oxide structure having the metal oxide whiskers on the surface of the substrate.

It is preferable that the metal oxide which becomes the raw material constituting the metal oxide structure to be used as the light emitting electrode in the present invention has the same metal in the metal oxide of the structure to be targeted, react with a compound contained in the air such as oxygen or moisture, to thereby form an oxide. However, a substance which is ordinarily not present in the air, for example, ozone or the like is supplied in an atmosphere in which the metal compound is blown to allow the substance to be present therein and, then, such metal compound as reacts with the substance to form the oxide is permissible.

As for such metal compounds as described above, for example, alkoxides in which hydrogen of a hydroxyl group of an alcohol is substituted by a metal or an element analogous to the metal; various types of metal or metal-like complexes having one, two or more types of ligands selected from among acetylacetone, ethylene diamine, bipiperidine, bipyrazine, cyclohexane diamine, tetraazacyclotetradecane, ethylene diamine tetraacetic acid, ethylene-bis(guanide), ethylene-bis(salicylamine), tetraethylene glycol, aminoethanol, glycine, triglycine, naphthylidine, phenanthronine, pentane diamine, pyridine, salicyl aldehyde, salicylidene amine, porphyrin, thiourea and the like; various types of metal carbonyls such as Fe, Cr, Mn, Co, Ni, Mo, V, W and Ru each having a carbonyl group(s) as a ligand(s); further, various types of metal compounds having one, two or more ligands selected from among a carbonyl group, an alkyl group, an alkenyl group, a phenyl or an alkylphenyl group, an olefin group, an aryl group and conjugated diene groups such as a cyclobutadiene group, dienyl groups such as a cyclopentadienyl group, triene groups, arene groups and trienyl groups such as a cycloheptatrienyl group; and halogenated metal compounds can be used. Further, other metal complexes can be used. Among other things, a metal acetylacetonato compound, a metal alkoxide compound and the like are favorably used.

As for other favorable complexes, compounds in which one, two or more ligands such as β-diketones, keto esters, hydroxycarboxylic acids or salts thereof, various types of Schiff bases, keto alcohols, polyamines, alkanol amines, enolic active hydrogen compounds, dicarboxylic acids, glycols and ferrocenes are bonded to a metal can be used.

When the element different from the main material which constitutes the whiskers is contained in the whiskers, an amount of such element of different type to be contained is not particularly limited; however, it is, ordinarily, preferable that the element is contained in an amount, based on the element which constitutes the main material, of from about 0.1 to about 20% by atom.

As for the carrier gas, unless it reacts with the metal compound to be used, no particular restriction is put thereon. As for a specific example, an inert gas such as a nitrogen gas or any one of helium, neon and argon, a carbon dioxide gas, an organic fluorine gas, or an organic material such as heptane or hexane can be used. There among, from the standpoint of safety and economy, the inert gas is preferable. The nitrogen gas is the most preferable from the economical point of view.

As for substrates, on which the metal oxide structure having the whiskers is produced, to be used as the light emitting electrode in the present invention, for example, inorganic glass such as soda lime glass, a metal such as stainless steel, a semiconductor crystal such as silicon and the metal oxides such as aluminum oxide, magnesium oxide and strontium titanate are listed. The crystals in this case may be one or more types of mono-crystals, a poly-crystal, one or more types of semi-crystalline substances containing simultaneously a non-crystalline portion and a crystalline portion, or mixtures thereof.

As for preferable substrates, metals including silicon, metal oxides, and semiconductor crystals such as ZnTe, GaP, GaAs and InP can be used.

When the mono-crystal comprising a metal oxide or a semiconductor is used as the substrate, it is preferable to select a mono-crystal species of the substrate in which a lattice constant is near to that of a crystal species of the metal oxide (whiskers) which is epitaxially grown on a surface of the substrate. A measurement of the lattice constant can be performed by a conventionally known method such as a wide-angle X-ray diffraction method. It is preferable to select the mono-crystal species forming the substrate in which a ratio (A/B) of a lattice contant (A) of a contact face between the mono-crystal species forming the protrusion (whiskers) and the substrate to a lattice constant (B) of a contact face between the mono-crystal species forming the substrate and the protrusion is from 0.8 to 1.2, it is more preferable to select the mono-crystal species in which the ratio (A/B) is from 0.9 to 1.1 and it is particularly preferable to select the mono-crystal species in which the ratio (A/B) is from 0.95 to 1.05.

As for a particularly preferable mono-crystal species which becomes the substrate, silicon or a metal oxide such as aluminum oxide, magnesium oxide or SiTiO₃ can be used. The substrate may comprise one or more types of mono-crystals or poly-crystals, one or more types of semiconductor material simultaneously containing a non-crystal portion and a crystal portion, or mixtures thereof. However, that comprising one type of mono-crystal is the most preferable.

A temperature of the substrate on which the metal oxide structure having the whiskers is formed is not particularly limited, so long as it is a temperature at which the metal oxide is formed in the vicinity of and on the surface of the substrate; however, it is preferable to set the temperature higher than that of the raw material gas to be blown on the surface of the substrate and, ordinarily, the temperature is set to be from 100 to 700° C.

A reaction time necessary for forming the metal oxide structure having the whiskers is appropriately selected in accordance with types of raw materials, reaction conditions, applications of the structure to be targeted and the like.

The metal oxide structure having the whiskers can be obtained ordinarily in a state in which the whiskers are formed in a dense state and a space is present between whiskers. Therefore, the structure may be deformed depending on usage patterns and the like at the time it is actually used. Namely, many of whiskers may be leveled off to the ground by a physical stress. In order to prevent such feature, it is also possible to fill-fix the space between the whiskers with a substance which does not hinder the light emission, for example, an organic substance such as a thermoplastic resin, a thermosetting resin, an elastomer, an instant adhesive such as cyanoacrylate or the like; an inorganic substance such as glass, ceramics or the like; a metal or the like.

As for such thermoplastic resins to be used for fill-fixing the space between whiskers, low-, medium- or high-density polyethylene, polypropylene, polymethyl pentene, polyvinyl chloride, polystyrene, an acrylonitrile-styrene copolymer (hereinafter, referred to also as “SAN resin” in short), an acrylonitrile-butadiene-styrene copolymer (hereinafter, referred to also as “ABS resin” in short), polyamide, polyacetal, polycarbonate, polyethylene terephthalate, polybutylene terephthalate, polyphenylene ether, polymethylmethacrylate, polyether imide, polysulfone, polyester imide, polyarylate, polyphenylene sulfite, a styrene-butadiene copolymer, a hydrogenated composition thereof or the like, and polymer blends or copolymers of combinations of two or more types thereof, such as a combination of polycarbonate and an acrylonitrile-butadiene-styrene copolymer and a combination of polyphenylene ether and polystyrene are listed.

Further, as for such thermosetting resins to be used for fill-fixing the space between whiskers, an epoxy resin, a DFK resin, a xylene resin, a guanamine resin, a diallyl phthalate resin, a vinyl ester resin, a phenol resin, an unsaturated polyester resin, a furan resin, polyimide, poly(p-hydroxybenzoic acid), polyurethane, a maleic acid resin, a melamine resin, a urea resin and the like are listed. As for such elastomers to be used for fixing the whiskers, natural rubber and synthetic rubbers such as a butadiene rubber, a silicone rubber, a polyisoprene rubber, a chloroprene rubber, an ethylene-propylene rubber, a butyl rubber, an isobutylene rubber, a styrene-butadiene rubber, a styrene-isoprene-styrene block copolymer rubber, an acrylic rubber, an acrylonitrile-butadiene rubber, a hydrochlorinated rubber, a chlorosulfonated polyethylene rubber and a polysulfide rubber are listed. Other than these rubbers, polytetrafluoroethylene, a petroleum resin, analkyd resin and the like can be used.

The light emitting device according to the present invention is constituted by allowing the light emitting electrode comprising the metal oxide structure having the whiskers of the metal oxide as has been described and the cold cathode to be disposed opposite to each other in the vacuum chamber or the container having the gas sealed therein.

The material to constitute the cold cathode of the light emitting device is not particularly limited and any material which is ordinarily used as the cold cathode can be used. As for preferable materials in this occasion, the metal oxide structure having the whiskers(including the whiskers comprising the element different from the main material) to be used in the light emitting electrode, an article in which the tip portions of the whiskers of the metal oxide structure are covered with an electrically conductive material and the like can be used. Further, as for other preferable materials, carbonaceous material such as a carbon nanotube, fullerene, diamond grains, graphite grains and a carbon fiber are listed.

Next, the light emitting device according to the present invention is further described with reference to drawings; however, the present invention is not limited to embodiments to be described below.

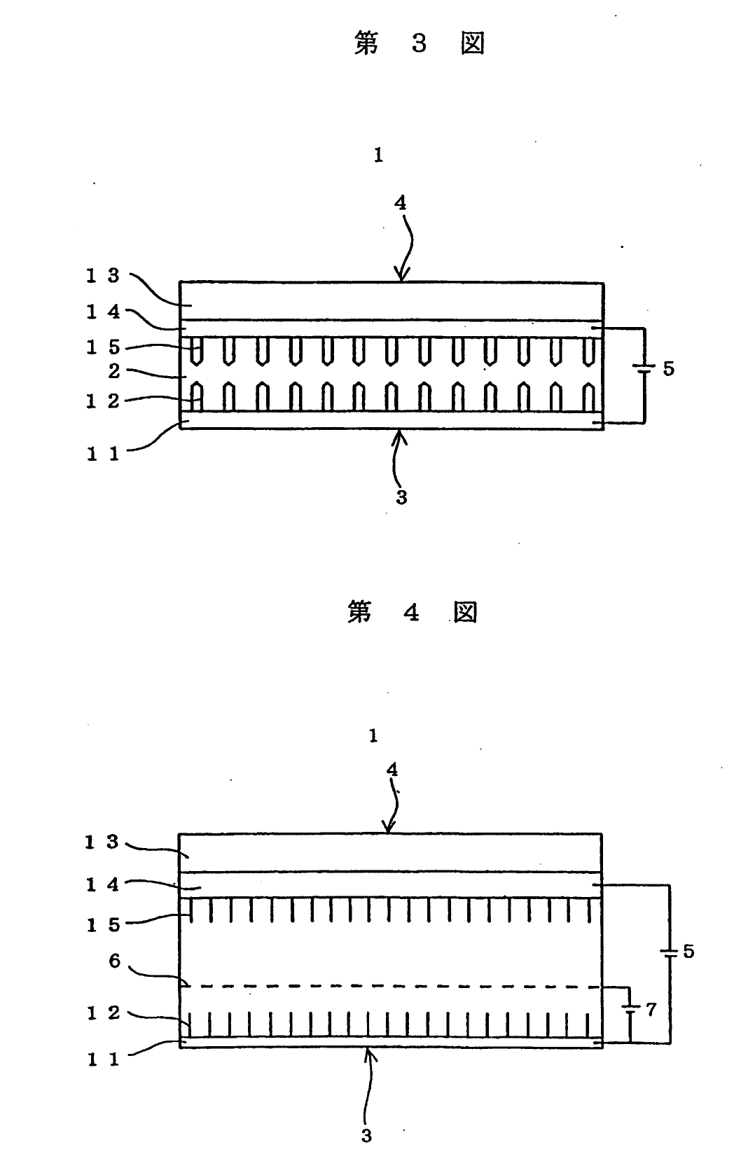

FIG. 3 is a schematic diagram showing an example of a light emitting device according to the present invention. In a light emitting device 1, a cold cathode 3 and a light emitting electrode 4 are disposed opposite to each other in a vacuum glass tube 2. The cold cathode 3 is constituted by a material in which whiskers 12 of a metal oxide are formed on a surface of a metal substrate 11 by an atmospheric open type CVD method. Further, the light emitting electrode 4 is constituted by a material in which a transparent electrically conductive film 14 comprising ITO, SnO₂, ZnO or the like is formed on a surface of a glass substrate 13 and, then, whiskers 15 of a metal oxide are formed on the resultant surface thereof by the atmospheric open type CVD method. A direct current power supply 5 is provided between the cold cathode 3 and the light emitting electrode 4 and, then, a bias voltage is applied. It is possible to use a high frequency power supply in place of the direct current power supply (in light emitting devices to be described below, the same holding true).

Electrons are emitted in vacuum from tips of the whiskers 12 of the cold cathode 3 applied with voltage and the thus-emitted electrons are accelerated by an electric field generated by the direct current power supply 5 and bombarded with the whiskers of the metal oxide 15 of the light emitting electrode 4, to thereby generate free exciton luminescence having an energy approximately equal to a band gap of the metal oxide constituting the whiskers. Since the free exciton luminescence is extremely strong, the glass substrate 13 of the light emitting electrode 4 becomes a strong light emitting face. The glass substrate 13 may be constituted by a tube wall itself of the glass tube 2.

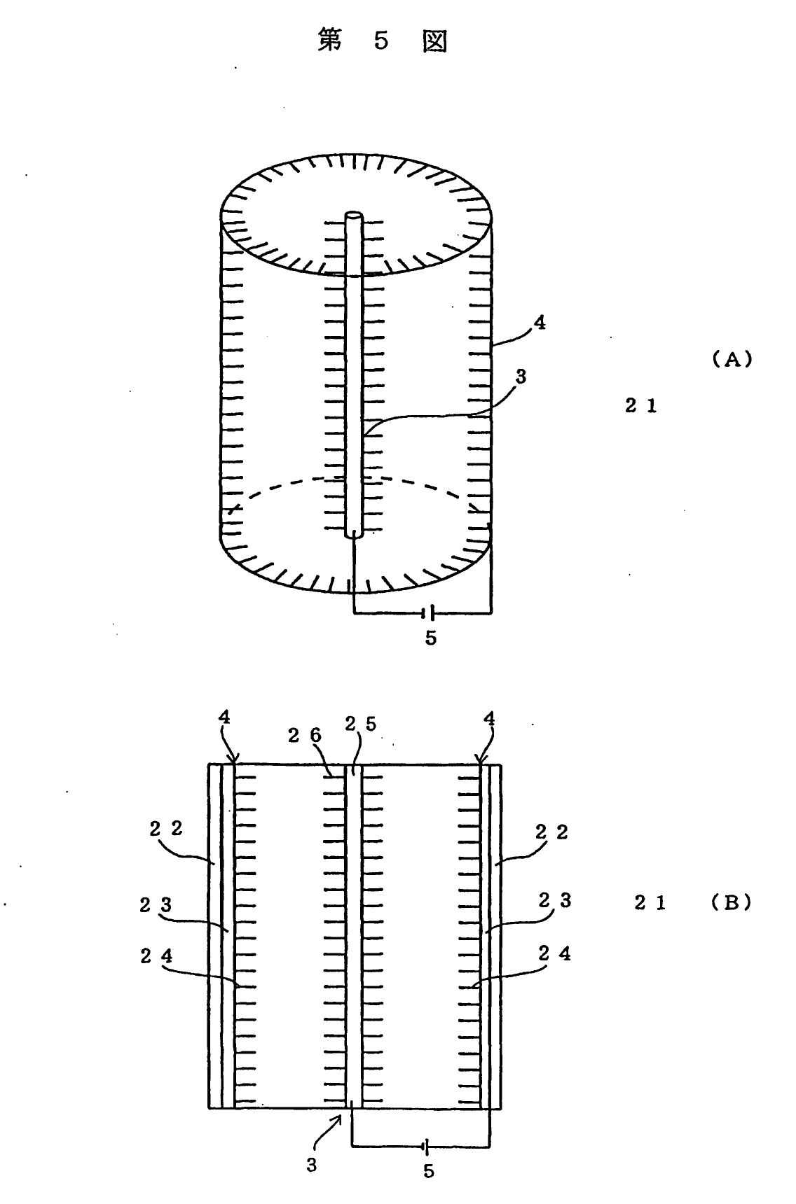

FIG. 4 is a schematic diagram showing another example of a light emitting device according to the present invention. The light emitting device 1 is constituted such that an electron accelerating electrode 6 is provided between the cold cathode 3 and the light emitting electrode 4 and the electrons emitted from the tips of the whiskers 12 of the cold cathode 3 are further accelerated by being applied with voltage by the direct current power supply 7. As the electron accelerating electrode 6, a mesh material constituted by, for example, a metal material such as copper or SUS or the like can be used. A size of the mesh material is not particularly limited and, for example, the mesh material in which thickness of a wire material constituting a mesh is from about 10 to about 500 μm and each side of the mesh formed by vertical and horizontal wire materials is about 0.5 to about 10 μm can be used.

Other constitutions of the light emitting device 1 are same as those of the light emitting device as shown in FIG. 3.

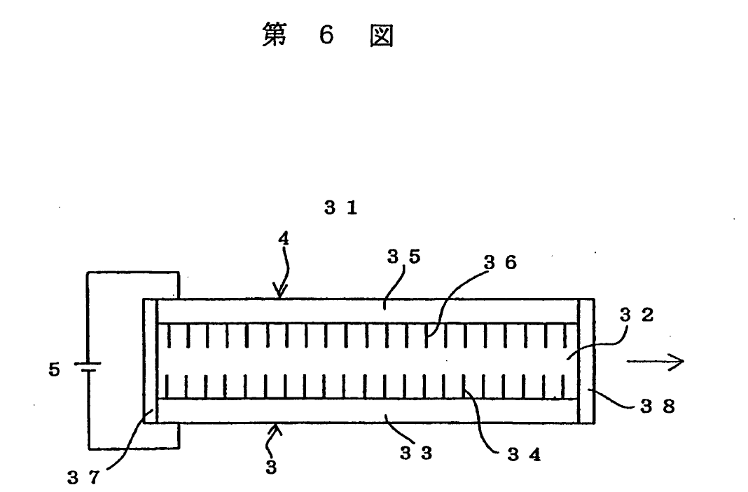

FIG. 5 shows schematic diagrams of still another example of a light emitting device according to the present invention, wherein (A) shows a perspective diagram thereof and (B) shows a cross-sectional diagram.

In a light emitting device 21, an electrically conductive film 23 comprising a metal oxide or the like is provided on an inner surface of a vacuum cylindrical glass tube 22 and, then, whiskers 24 of a metal oxide are formed on the surface of the thus-provided electrically conductive film 23 by the atmospheric open type CVD method, to thereby constitute the light emitting device 4. Further, the light emitting device 21 is constituted such that the cold cathode 3 in which whiskers 26 of a metal oxide are formed on a surface of a cylindrical electrically conductive substrate 25 by the atmospheric open type CVD method is provided in a central portion of the glass tube 22 and, then, the direct current power supply 5 is provided between the cold cathode 3 and the light emitting electrode 4, to thereby apply the bias voltage.

In the light emitting device 21, the electrons emitted from the tips portion of the whiskers 26 of the cold cathode 3 disposed in the central portion of the glass tube 22 are bombarded with the whiskers 24 provided on the surface of the inner wall of the glass tube 22 and, then, allow the free exciton luminescence having an energy approximately equal to the band gap of the metal oxide constituting the whiskers to be generated from an entire surface of the tube wall of the glass tube 22.

FIG. 6 is a schematic diagram showing still another example of a light emitting device according to the present invention. In a light emitting device 31, the cold cathode 3 constituted by a material in which whiskers 34 of a metal oxide are formed on a surface of a substrate 33 by the atmospheric open type CVD method and the light emitting electrode 4 constituted by a material in which whiskers 36 are formed on a surface of a substrate 35 by the atmospheric open type CVD method are disposed opposite to each other in a vacuum light-non-transmissive container 32. The light emitting device 31 is constituted such that the direct current power supply 5 is provided between the cold cathode 3 and the light emitting electrode 4, to thereby apply a bias voltage. Further, a reflective plate 37 such as a mirror is provided on one side face of a space defined by the cold cathode 3 and the light emitting electrode 4 and a light semi-transmissive plate 38 such as a half-mirror is provided on another side thereof.

In the light emitting device 31, electrons emitted from tip portions of the whiskers 34 of the cold cathode 3 are bombarded with the whiskers 36 of the light emitting electrode 4 and, then, allow the free exciton luminescence having an energy approximately equal to the band gap of the metal oxide constituting the whiskers to be generated and, subsequently, the resultant light is reflected by the reflecting plate 37 provided on the side face, transmitted through the light semi-transmissive plate 38 on another side face and emitted in a direction denoted by an arrow mark.

In the above-described embodiments, an example in which the cold cathode of the light emitting device is constituted by the metal oxide structure having the whiskers of the metal oxide in a same manner as in the light emitting electrode has been explained; however, it goes without saying that any of other materials such as carbonaceous material, for example, a carbon nanotube, fullerene, diamond grains, graphite grains and a carbon fiber can be used as a material constituting the cold cathode.

Further, as the container containing the cold cathode and the light emitting electrode, the container having a gas sealed therein may of course be used in place of the vacuum chamber.

### EXAMPLES

Next, the present invention will be described in detail with reference to examples; however, the present invention is not limited thereto.

In a light emitting device according to the present invention, a metal oxide structure having whiskers of a metal oxide to be used as a material which constitutes a light emitting electrode or a cold cathode can be produced by an ordinary method by using an atmospheric open type CVD method as shown in FIG. 1 or 2.

### Example 1

Zn (C₅H₇O₂)₂ as a raw material was vaporized at a vaporizing temperature of 115° C. in a N₂ gas flow rate of 1.2 dm³/min by using an apparatus as shown in FIG. 1 and, then, blown on a transparent glass substrate which was coated with a transparent electrically conductive film and heated at 550° C. from a nozzle in a slit shape, to thereby grow ZnO whiskers oriented to <0001>. Such whiskers each having a length of 40 μm and a diameter of 2 μm were formed on a surface of the substrate in a dense state. The resultant article was defined as a light emitting electrode.

Zn (C₅H₇O₂)₂ and Al (C₅H₇O₂)₃ as raw materials were vaporized at a vaporizing temperature of 115° C. in a N₂ gas flow rate of 1.2 dm³/min by using an apparatus as shown in FIG. 2 and, then, blown on an aluminum substrate which was heated at 550° C. from a nozzle in a slit shape, to thereby grow Al:ZnO whiskers oriented to <0001>. Such whiskers each having a length of 40 μm and a diameter of 2 μm were formed on a surface of the substrate in a dense state. Further, surfaces of the Al:ZnO whiskers were coated with a carbon nitride film having a thickness of 20 nm by using a plasma CVD apparatus and the resultant article was defined as a cold cathode.

A light emitting device as shown in FIG. 3 was formed by disposing the above-described light emitting electrode and the cold cathode opposite to each other with a space of 100 μm therebetween in a vacuum glass tube. When the light emitting device was applied with a direct current voltage of 2 kV, a strong ultraviolet ray emission having a center wave length of 378 nm was obtained from the light emitting electrode.

### Example 2

Ti (OC₃H₇)₂ as a raw material was vaporized at a vaporizing temperature of 115° C. in a N₂ gas flow rate of 1.2 dm³/min by using an apparatus as shown in FIG. 1 and, then, blown on a transparent glass substrate which was coated with a transparent electrically conductive film and heated at 550° C. from a nozzle in a slit shape, to thereby grow TiO₂ whiskers oriented to <112>. Such whiskers each having a length of 20 μm and a diameter of 5 μm were formed on a surface of the substrate in a dense state. The resultant article was defined as a light emitting electrode.

Zn (C₅H₇O₂)₂ and Al (C₅H₇O₂)₃ as raw materials were vaporized at a vaporizing temperature of 115° C. in a N₂ gas flow rate of 1.2 dm³/min by using an apparatus as shown in FIG. 2 and, then, blown on an aluminum substrate which was heated at 550° C. from a nozzle in a slit shape, to thereby grow Al:ZnO whiskers oriented to <0001>. Such whiskers each having a length of 40 μm and a diameter of 2 μm were formed on a surface of the substrate in a dense state. Further, surfaces of the Al:ZnO whiskers were coated with a carbon nitride film having a thickness of 20 nm by using a plasma CVD apparatus and the resultant article was defined as a cold cathode.

A light emitting device as shown in FIG. 4 was formed by disposing the above-described light emitting electrode and the cold cathode opposite to each other with a space of 5 mm therebetween and providing an accelerating electrode made of SUS316 in a mesh state (thickness: 100 μm; vertical and horizontal sizes of each mesh: 1 mm×1 mm) in a distance of 100 μm from the cold cathode in a vacuum glass tube. When a direct current voltage of 2 kV and a direct current voltage of 5 kV were applied to a bias voltage and an accelerating voltage, respectively, a strong ultraviolet ray emission having a center wavelength of 383 nm was obtained from the light emitting electrode.

### Example 3

In (C₅H₇O₂)₄ and Sn (C₅H₇O₂)₄ as raw materials were vaporized at a vaporizing temperature of 125° C. in a N₂ gas flow rate of 1.2 dm³/min by using an apparatus as shown in FIG. 2 and, then, blown on an inner surface of a transparent cylindrical glass tube which was heated at 550° C. from a nozzle in a slit shape, to thereby grow Sn:In₂O₃ whiskers oriented to <100>. Such whiskers each having a length of 40 μm and a diameter of 2 μm were formed on the inner surface of the glass tube in a dense state. The resultant article was defined as a light emitting electrode.

Zn (C₅H₇O₂)₂ and Al (C₅H₇O₂)₃ as raw materials were vaporized at a vaporizing temperature of 115° C. in a N₂ gas flow rate of 1.2 dm³/min by using an apparatus as shown in FIG. 2 and, then, blown on an aluminum rod which was heated at 550° C. from a nozzle in a slit shape, to thereby grow Al:ZnO whiskers oriented to <0001>. Such whiskers each having a length of 40 μm and a diameter of 2 μm were formed on a surface of the substrate in a dense state. Further, surfaces of the Al:ZnO whiskers were coated with a carbon nitride film having a thickness of 20 nm by using a plasma CVD apparatus and the resultant article was defined as a cold cathode.

A light emitting device as shown in FIG. 5 was formed by disposing an aluminum-rod cold cathode in a transparent cylindrical glass tube, being a light emitting electrode, in which the whiskers were formed on the inner surface. When an inside of the light emitting device was allowed to be in vacuum and, then, a direct current voltage of 2 kV was applied to a bias voltage, a strong ultraviolet ray emission having a center wavelength of 378 nm was obtained from the light emitting electrode.

### Example 4

Zn (C₅H₇O₂)₂ as a raw material was vaporized at a vaporizing temperature of 115° C. in a N₂ gas flow rate of 1.2 dm³/min by using an apparatus as shown in FIG. 1 and, then, blown on a transparent glass substrate which was coated with a transparent electrically conductive film and heated at 550° C. from a nozzle in a slit shape, to thereby grow ZnO whiskers oriented to <0001>. Such whiskers each having a length of 40 μm and a diameter of 2 μm were formed on a surface of the substrate in a dense state. The resultant article was defined as a light emitting electrode.

Zn (C₅H₇O₂)₂ and Al (C₅H₇O₂)₃ as raw materials were vaporized at a vaporizing temperature of 115° C. in a N₂ gas flow rate of 1.2 dm³/min by using an apparatus as shown in FIG. 2 and, then, blown on an aluminum substrate which was heated at 550° C. from a nozzle in a slit shape, to thereby grow Al:ZnO whiskers oriented to <0001>. Such whiskers each having a length of 40 μm and a diameter of 2 μm were formed on a surface of the substrate in a dense state. Further, surfaces of the Al:ZnO whiskers were coated with a carbon nitride film having a thickness of 20 nm by using a plasma CVD apparatus and the resultant article was defined as a cold cathode.

A light emitting device as shown in FIG. 6 was formed by disposing the above-described light emitting electrode and the cold cathode opposite to each other with a space of 100 μm therebetween and providing a mirror and a half mirror on faces of both sides, respectively, of a space defined by the light emitting electrode and the cold cathode in a vacuum glass tube. When a direct current voltage of 2 kV was applied to a bias voltage, a strong ultraviolet ray laser having a center wavelength of 378 nm was obtained from the light emitting electrode.

### INDUSTRIAL APPLICABILITY

According to the present invention, a light emitting device capable of emitting light not only in a visible light region but also in an ultraviolet ray region and an infrared ray region with a high luminance can be produced at a low cost. Since, the light emitting device according to the present invention can obtain a free exciton luminescence approximately equal to a band gap of a metal oxide constituting a light emitting electrode, it is possible to remarkably reduce a size of an apparatus compared with a conventional light emitting device. Therefore, the light emitting device according to the present invention can widely be used in light sources of, for example, various types of displays, OA apparatuses and optical communication systems, and lighting fixtures and, accordingly, is extremely high in a practical value.

1. A light emitting device, wherein a light emitting electrode and a cold cathode are disposed opposite to each other, wherein the light emitting electrode and the cold cathode are respectively constituted by a metal oxide structure having whiskers of a metal oxide grown on a surface of a substrate by CVD.

2. The light emitting device according to claim 1, wherein a band gap of the metal oxide constituting the whiskers is from 1.5 to 7.7 eV.

3. The light emitting device according to claim 1 wherein a diameter of a cross-section of an approximate circle of the whisker is from 0.01 to 100 μm and a ratio of length of the whisker to the diameter of the cross-section of the approximate circle of the whisker is from 1 to 10000.

4. The light emitting device according to claim 1, wherein the whiskers are present in a density of from 0.1 to 10000 pieces per area of 10 μm×10 μm on a surface of the metal oxide.

5. The light emitting device according to claim 1, wherein the whiskers comprise an element different from that of a main material which constitutes the whiskers.

6. The light emitting device according to claim 1, wherein the whiskers can be obtained by allowing the metal oxide to be epitaxially grown on a surface of a substrate.

7. The light emitting device according to claim 1, wherein zinc oxide is used as the main material which constitutes the whiskers.

8. The light emitting device according to claim 1, wherein a light emitting electrode is constituted by the metal oxide structure in which spaces between whiskers are filled with a material selected from among an organic substance, an inorganic substance and a metal.

9-10. (canceled)

11. The light emitting device according to claim 1, wherein the light emitting electrode and the cold cathode are disposed in a vacuum chamber or a container having a gas sealed therein.

12. The light emitting device according to claim 1, wherein the light emitting electrode in a planar shape and the cold cathode in a planar shape are disposed opposite to each other in the container.

13. The light emitting device according to claim 12, wherein a reflecting plate is provided on one side face of a space defined by the light emitting electrode and the cold cathode.

14. The light emitting device according to claim 11, wherein the light emitting electrode is disposed on an inner surface of the container and the cold cathode is disposed in a center portion of the container.

15. The light emitting device according to claim 12, wherein an electron accelerating electrode is provided between the cold cathode and the light emitting electrode.

16. The light emitting device according to claim 1, wherein the light emitting device emits light in an ultraviolet ray region.
